(19) United States
(12) Patent Application Publication
(10) Pub. No.: US 2020/0395463 A1
(43) Pub. Date: Dec. 17, 2020

(54) METHOD OF FABRICATING A SEMICONDUCTOR DEVICE

(71) Applicant: Samsung Electronics Co., Ltd., Suwon-si (KR)

(72) Inventors: Byungjae PARK, Seongnam-si (KR); Miji LEE, Yongin-si (KR); Sangwoo PAE, Suwon-si (KR); Hwasung RHEE, Seongnam-si (KR)

(73) Assignee: Samsung Electronics Co., Ltd., Suwon-si (KR)

(21) Appl. No.: 16/705,772

(22) Filed: Dec. 6, 2019

(30) Foreign Application Priority Data
Jun. 11, 2019 (KR) 10-2019-0068736

(51) Int. Cl. H01L 29/66; H01L 21/3213; H01L 21/762; H01L 29/06; H01L 29/423

(52) U.S. Cl. CPC H01L 29/66545; H01L 29/6656; H01L 21/32133; H01L 29/66795; H01L 21/76224; H01L 29/0673; H01L 29/42392; H01L 21/32139

(57) ABSTRACT

According to an embodiment of inventive concepts, a method of fabricating a semiconductor device may include forming an active pattern on a substrate, forming a first dummy gate pattern on the active pattern, forming a spacer pattern to cover a side surface of the first dummy gate pattern, and forming a source/drain pattern at a side of the first dummy gate pattern. The first dummy gate pattern may extend to cross the active pattern. The spacer pattern may be between the side surface of the first dummy gate pattern and a side surface of the source/drain pattern. The first dummy gate pattern may include a first semiconductor material and a second semiconductor material that may be different from the first semiconductor material.

### CROSS-REFERENCE TO RELATED APPLICATIONS

This U.S. non-provisional patent application claims priority under 35 U.S.C. § 119 to Korean Patent Application No. 10-2019-0068736, filed on Jun. 11, 2019, in the Korean Intellectual Property Office, the entire contents of which are hereby incorporated by reference.

### BACKGROUND

The present disclosure relates to a semiconductor device, and in particular, to a method of fabricating a semiconductor device including a field effect transistor.

Due to their small-sized, multifunctional, and/or low-cost characteristics, semiconductor devices are being esteemed as important elements in the electronic industry. As the electronics industry develops, there is a growing demand for semiconductor devices with improved characteristics. To meet such a demand, complexity and/or integration density of semiconductor devices are increasing.

### SUMMARY

An embodiment of inventive concepts provides a method of fabricating a highly reliable semiconductor device.

According to an embodiment of inventive concepts, a method of fabricating a semiconductor device may include forming an active pattern on a substrate; forming a first dummy gate pattern, which is extended to cross the active pattern, on the active pattern; forming a spacer pattern to cover a side surface of the first dummy gate pattern; and forming a source/drain pattern at a side of the first dummy gate pattern. The spacer pattern may be between the side surface of the first dummy gate pattern and a side surface of the source/drain pattern, and the first dummy gate pattern may include a first semiconductor material and a second semiconductor material different from the first semiconductor material.

According to an embodiment of inventive concepts, a method of fabricating a semiconductor device may include forming a trench on a substrate, the trench defining an active pattern; forming a device isolation pattern to cover a lower portion of the trench; forming a first dummy gate pattern on the active pattern and the device isolation pattern, the first dummy gate pattern crossing over the active pattern and the device isolation pattern; and forming a second dummy gate pattern on the first dummy gate pattern. A top surface of the first dummy gate pattern on the device isolation pattern may be provided at a level that may be equal to or higher than a top surface of the active pattern.

According to an embodiment of inventive concepts, a method of fabricating a semiconductor device may include forming an active pattern, which has an upward protruding shape, on a substrate, and forming a dummy gate pattern on the active pattern. The dummy pattern may cross the active pattern and extend in a direction. The forming the dummy gate pattern may include forming a first dummy gate pattern to cover a side surface of the active pattern and forming a second dummy gate pattern on the first dummy gate pattern. The first dummy gate pattern may include a first semiconductor material and a second semiconductor material that may be different from the first semiconductor material.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view of a semiconductor device according to an embodiment of inventive concepts.

FIGS. 2A to 2I are sectional views illustrating a method of fabricating a semiconductor device according to an embodiment of inventive concepts.

FIGS. 3A to 3C are sectional views illustrating a method of fabricating a semiconductor device according to an embodiment of inventive concepts.

FIGS. 4A to 4G are sectional views illustrating a method of fabricating a semiconductor device according to an embodiment of inventive concepts.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

A semiconductor device and a method of fabricating the same, according to an embodiment of inventive concepts, will be described below.

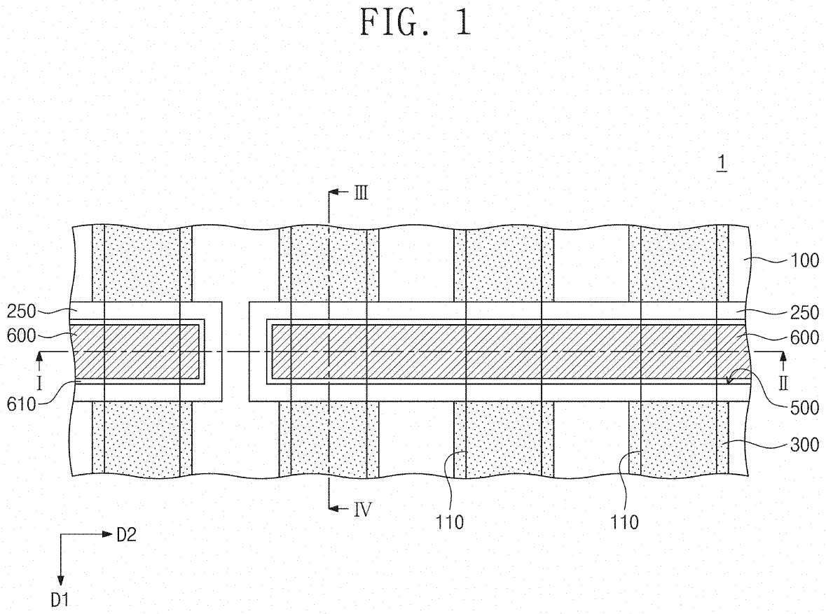

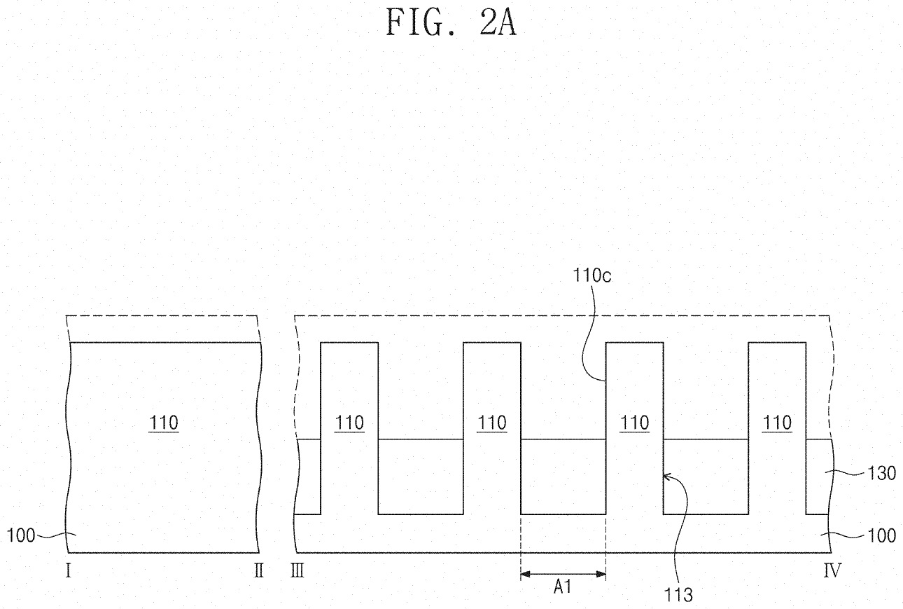

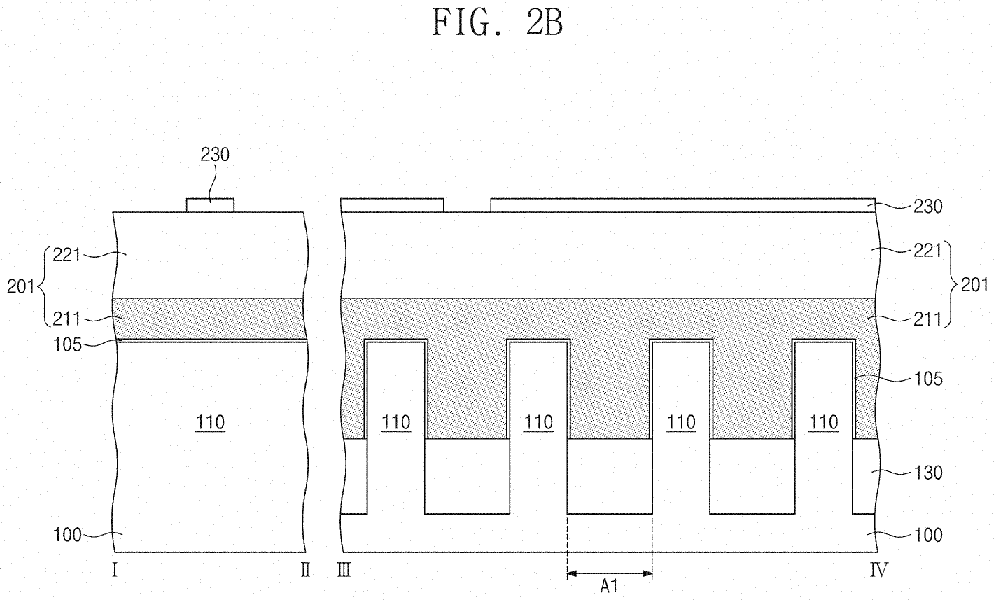

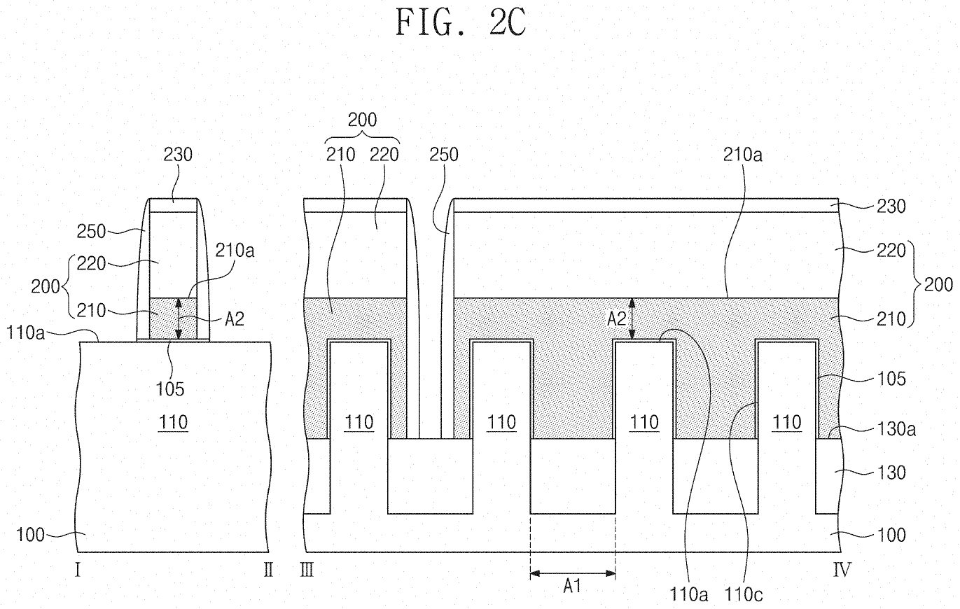

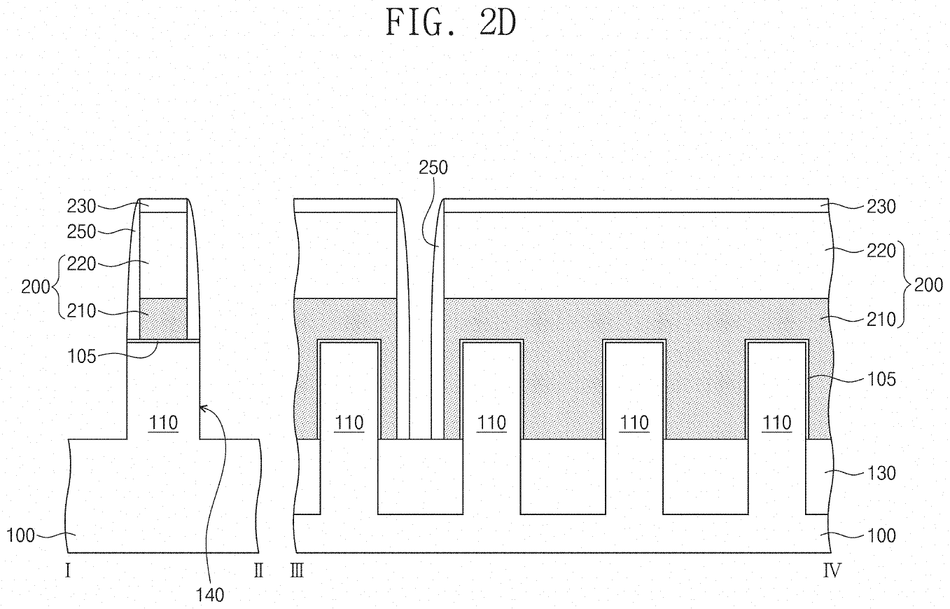

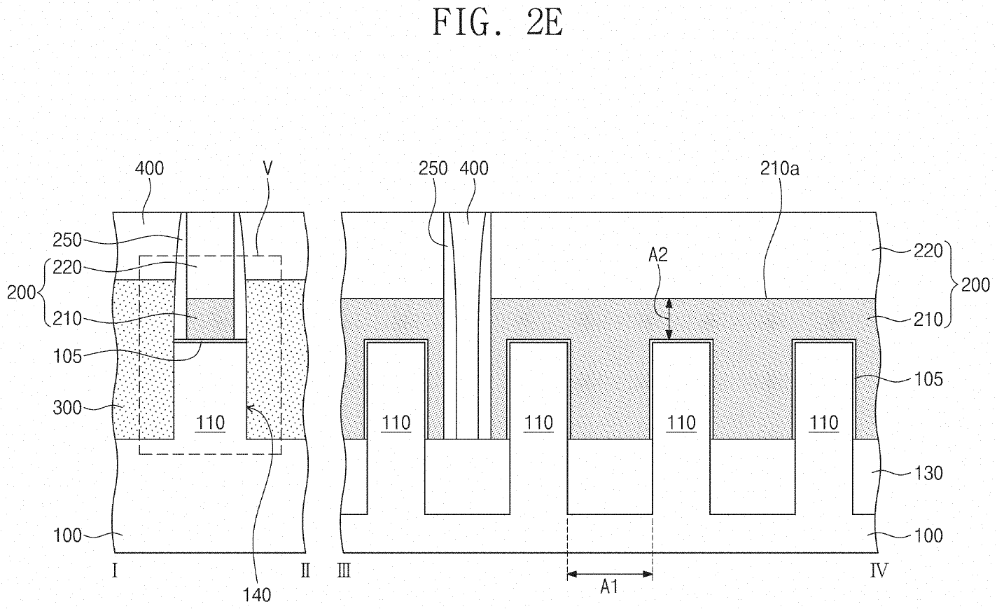

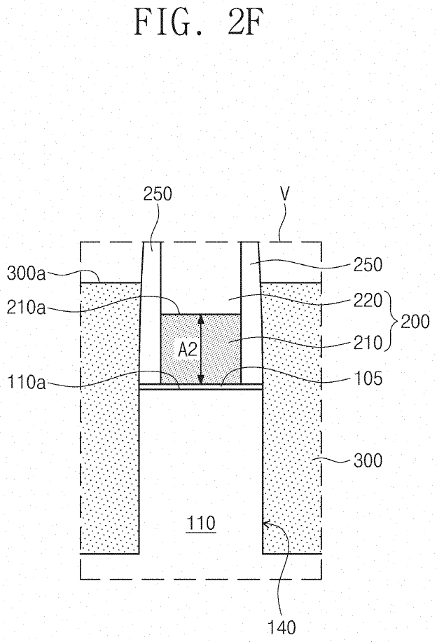

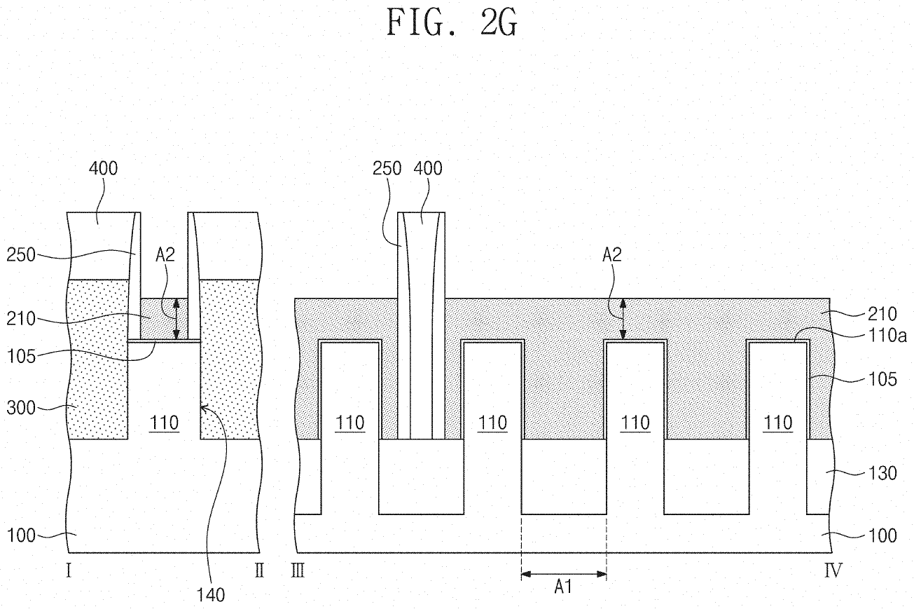

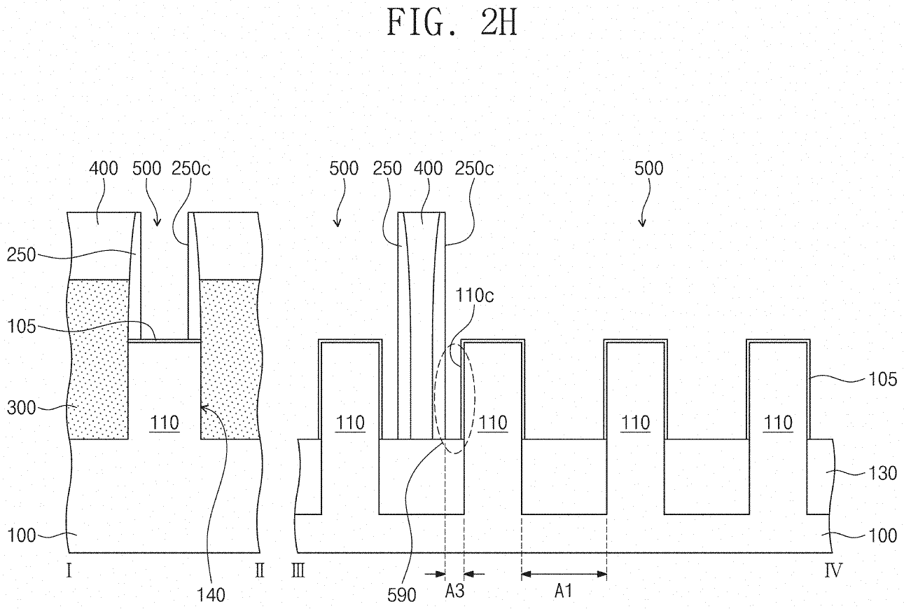

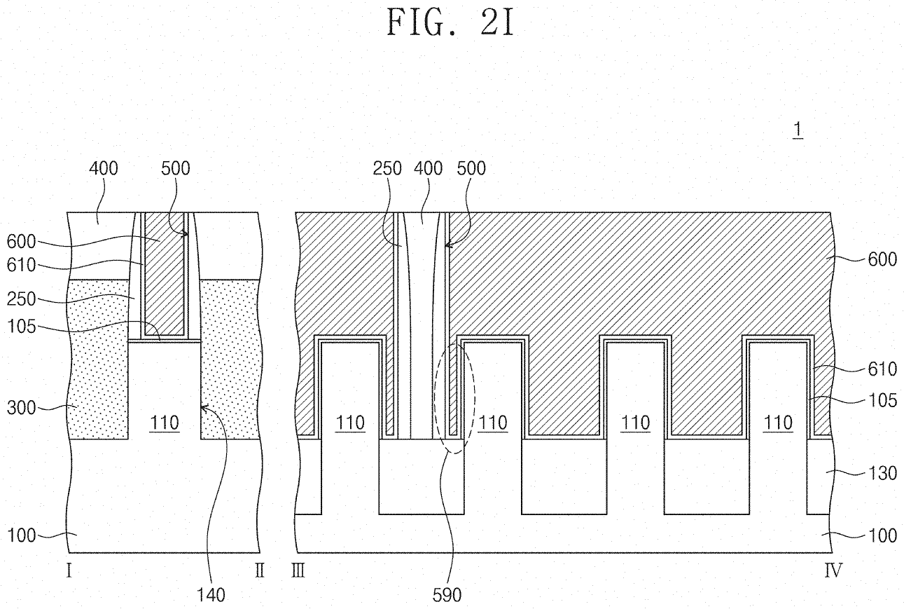

FIG. 1 is a plan view of a semiconductor device according to an embodiment of inventive concepts. FIGS. 2A to 2I are sectional views illustrating a method of fabricating a semiconductor device according to an embodiment of inventive concepts. In detail, FIGS. 2A to 2E and 2G to 2I are sectional views taken along lines I-II and III-IV of FIG. 1, and FIG. 2F is an enlarged sectional view of a portion V of FIG. 2E.

Referring to FIGS. 1 and 2A, a substrate 100 may be patterned to form an active pattern 110 and trenches 113. The trenches 113 may define the active pattern 110. The active pattern 110 may protrude above the substrate 100. The substrate 100 may be a semiconductor wafer a semiconductor-on-insulator wafer. As an example, the substrate 100 may be a silicon wafer, a silicon-germanium wafer, or a silicon-on-insulator (SOI) wafer. The formation of the trenches 113 may include forming a mask layer on the substrate 100 and anisotropically etching the substrate 100 using the mask layer as an etch mask. Thus, an active pattern 110 may have an upward protruding shape, on the substrate 100. Each of the trenches 113 may be a line-shaped structure extending in a first direction D1. The trenches 113 may be spaced apart from each other in a second direction D2. The first direction D1 may be parallel to a bottom surface of the substrate 100. The second direction D2 may be parallel to the bottom surface of the substrate 100 and may be substantially perpendicular to the first direction D1.

The active pattern 110 may be a line-shaped structure extending in the first direction D1. The active pattern 110 may include a plurality of active patterns 110. The active patterns 110 may be spaced apart from each other in the second direction D2. The active patterns 110 may be spaced apart from each other by a first distance A1. The first distance A1 may be the smallest distance between side surfaces 110c of two adjacent ones of the active patterns 110 and may be a distance measured in the second direction D2.

Device isolation patterns 130 may be formed in the trenches 113, respectively, to cover lower portions of the active patterns 110. Each of the device isolation patterns 130 may extend in the first direction D1. The formation of the device isolation patterns 130 may include forming an insulating layer on the active patterns 110 to fill the trenches 113 (as illustrated by the dotted line) and recessing the insulating layer to expose upper portions of the side surfaces 110c of the active patterns 110. Thus, the device isolation patterns 130 may be localized in the trenches 113, respectively, and may have top surfaces that are located at a level lower than top surfaces of the active patterns 110. The device isolation patterns 130 may be formed of or include at least one of silicon oxide, silicon nitride, and/or silicon oxynitride.

Referring to FIGS. 1 and 2B, an insulating pattern 105 and a dummy gate layer 201 may be formed on the active patterns 110. The insulating pattern 105 may be formed on the exposed upper portions of the active patterns 110 to conformally cover the top surfaces and the exposed side surfaces of the active patterns 110. The insulating pattern 105 may not extend onto the device isolation patterns 130. The insulating pattern 105 may be formed of or include a semiconductor oxide material (e.g., silicon oxide). In certain embodiments, the insulating pattern 105 may not be formed.

The formation of the dummy gate layer 201 may include forming a first dummy gate layer 211 and forming a second dummy gate layer 221. The first dummy gate layer 211 may be formed on the top and side surfaces of the active patterns 110 to cover the insulating pattern 105 and the device isolation pattern 130. The first dummy gate layer 211 may fill unfilled regions of the trenches 113, on the device isolation patterns 130. The first dummy gate layer 211 may be formed by a deposition process. The first dummy gate layer 211 may have a crystalline structure. For example, the first dummy gate layer 211 may include a first semiconductor material and a second semiconductor material, which is different from the first semiconductor material. For example, the first semiconductor material may be silicon, and the second semiconductor material may be germanium, but inventive concepts are not limited to this example. As an example, the first dummy gate layer 211 may include poly silicon-germanium.

The second dummy gate layer 221 may be formed on the first dummy gate layer 211. The second dummy gate layer 221 may include a material having an etch selectivity with respect to the first dummy gate layer 211. For example, the second dummy gate layer 221 may include the first semiconductor material but may not include the second semiconductor material. The second dummy gate layer 221 may have a crystalline structure. As an example, the second dummy gate layer 221 may include poly silicon.

A mask pattern 230 may be formed on the second dummy gate layer 221. The mask pattern 230 may be formed of or include at least one of, for example, silicon nitride, silicon carbo nitride, and/or silicon carbo oxynitride.

Referring to FIGS. 1 and 2C, an etching process may be performed to pattern the dummy gate layer 201, and as a result, a dummy gate pattern 200 may be formed. The mask pattern 230 may be used as an etch mask for the etching process. As a result of the patterning of the dummy gate layer 201, a plurality of dummy gate patterns 200, which are spaced apart from each other, may be formed. For convenience in description, one of the dummy gate patterns 200 will be mentioned in the following description. The formation of the dummy gate pattern 200 may include forming a first dummy gate pattern 210 and forming a second dummy gate pattern 220. The second dummy gate pattern 220 may be formed by patterning the second dummy gate layer 221, and the first dummy gate pattern 210 may be formed by patterning the first dummy gate layer 211.

The first dummy gate pattern 210 may extend in a direction parallel to the second direction D2, on the active patterns 110, and may cross the active patterns 110. The first dummy gate pattern 210 may be provided on top and side surfaces 110a and 110c of the active patterns 110. The dummy gate layer 201 may have a crystalline structure and may include the same material as the first dummy gate layer 211 described above. A top surface 210a of the first dummy gate pattern 210 may be located at a level that is equal to or higher than the top surfaces 110a of the active patterns 110. The top surface 210a of the first dummy gate pattern 210 on the top surfaces 110a of the active patterns 110 may be located at substantially the same level as the top surface 210a of the first dummy gate pattern 210 on the device isolation pattern 130.

The first dummy gate pattern 210 may include the second semiconductor material, and the second dummy gate pattern 220 may have a lattice constant different from that of the active patterns 110. Due to a difference in lattice constant between the first dummy gate pattern 210 and the active patterns 110, a stress may be exerted on the active patterns 110. For example, the stress may be a compressive force. In certain embodiments, the stress may be a tensile force. In the case where the first dummy gate pattern 210 does not cover the top surfaces 110a of the active patterns 110 or the first dummy gate pattern 210 on the active patterns 110 has an excessively small thickness A2, a strength of a stress exerted on the top surfaces 110a of the active patterns 110 may largely differ from a strength of a stress exerted on the side surfaces 110c of the active patterns 110. Here, the thickness A2 of the first dummy gate pattern 210 on the active patterns 110 may be said to be excessively small, when the thickness A2 of the first dummy gate pattern 210 on the top surfaces 110a of the active patterns 110 is smaller than 40% of the first distance A1. In an embodiment, the thickness A2 of the first dummy gate pattern 210 on the top surfaces 110a of the active patterns 110 may be 40% to 60% of the first distance A1 between the active patterns 110. Here, the thickness A2 of the first dummy gate pattern 210 on the top surfaces 110a of the active patterns 110 may correspond to a distance between the topmost surface of the insulating pattern 105 and the top surface 210a of the first dummy gate pattern 210. In the case where the insulating pattern 105 is omitted, the thickness A2 of the first dummy gate pattern 210 on the top surfaces 110a of the active patterns 110 may correspond to a distance between the top surfaces 110a of the active patterns 110 and the top surface 210a of the first dummy gate pattern 210. Accordingly, a strength of a stress, which is exerted on the top surfaces 110a of the active patterns 110 by the first dummy gate pattern 210, may be equal or similar to a strength of a stress exerted on the side surfaces 110c of the active patterns 110. A transistor, which is fabricated by the method according to an embodiment of inventive concepts, may exhibit improved reliability.

The second dummy gate pattern 220 may extend in a direction parallel to the second direction D2, on the first dummy gate pattern 210. The second dummy gate pattern 220 may have a crystalline structure and may include the same material as the second dummy gate layer 221 described above.

Spacer patterns 250 may be formed at both sides of the dummy gate pattern 200 and may cover side surfaces of the first and second dummy gate patterns 210 and 220. In an embodiment, a spacer layer (not shown) may be formed on the substrate 100 to cover the dummy gate pattern 200, the insulating pattern 105, the device isolation patterns 130, and the mask pattern 230. The spacer patterns 250 may be formed by performing an etching process on the spacer layer. The etching of the spacer layer may be performed in an anisotropic manner. The spacer patterns 250 may be formed to expose the active patterns 110 and at least one of the device isolation patterns 130. The spacer pattern 250 may be formed of or include at least one of, for example, silicon nitride, silicon carbo nitride, and/or silicon carbo oxynitride. During the etching of the spacer layer, a portion of the insulating pattern 105 may be etched along with the spacer layer.

Referring to FIGS. 1 and 2D, recess portions 140 may be formed in the active patterns 110 and at both sides of the dummy gate pattern 200. The formation of the recess portions 140 may include etching portions of the active patterns 110 using the mask pattern 230 and the spacer pattern 250 as an etch mask.

Referring to FIGS. 1, 2E, and 2F, source/drain patterns 300 may be formed on the active patterns 110 and at both sides of the dummy gate pattern 200. The source/drain patterns 300 may be formed in the recess portions 140, respectively. The source/drain patterns 300 may be grown from the recess portions 140 by a selective epitaxial growth process, in which the active patterns 110 are used as a seed layer.

The source/drain patterns 300 may be formed of or include at least one of silicon-germanium (SiGe), silicon (Si), or silicon carbide (SiC). The formation of the source/drain patterns 300 may further include doping the source/drain patterns 300 with impurities. As a result of the impurity doping, it may be possible to improve electric characteristics of a transistor including the source/drain patterns 300. In the case where the transistor is an NMOSFET, the impurity may be, for example, phosphorus (P), and in the case where the transistor is a PMOSFET, the impurity may be, for example, boron (B). The active patterns 110 between the source/drain patterns 300 may be used as a channel region of the transistor.

Top surfaces 300a of the source/drain patterns 300 may be located at a level higher than the top surfaces 110a of the active patterns 110, as shown in FIG. 2F. Thus, the spacer pattern 250 may be interposed between a side surface of the first dummy gate pattern 210 and a side surface of one of the source/drain patterns 300 adjacent thereto. In other words, the source/drain patterns 300 may be horizontally spaced apart from the first dummy gate pattern 210, with the spacer pattern 250 interposed therebetween. As described above, the thickness A2 of the first dummy gate pattern 210 on the top surfaces 110a of the active patterns 110 may be 40% to 60% of the first distance A1 between the active patterns 110.

As shown in FIG. 2E, an interlayered insulating layer 400 may be formed on the substrate 100 to cover the source/drain patterns 300 and the device isolation patterns 130. The formation of the interlayered insulating layer 400 may include forming a preliminary interlayered insulating layer on the substrate 100 to cover the source/drain patterns 300, the device isolation patterns 130, the spacer pattern 250, and the dummy gate pattern 200, and planarizing the preliminary interlayered insulating layer to expose the dummy gate pattern 200. The mask pattern 230 may be removed during the planarization step. The interlayered insulating layer 400 may be formed of or include at least one of, for example, silicon oxide, silicon nitride, silicon oxynitride, or low-k dielectric materials.

The interlayered insulating layer 400 may cover at least one of the device isolation patterns 130 exposed by the spacer pattern 250. In an embodiment, a plurality of the spacer patterns 250 may be provided, and a portion of the interlayered insulating layer 400 may fill a gap between adjacent ones of the spacer patterns 250. A portion of the interlayered insulating layer 400 may be used to separate gate patterns 600, which will be described with reference to FIG. 2I, from each other. For convenience in description, one of the spacer patterns 250 will be mentioned in the following description.

Referring sequentially to FIGS. 2G and 2H, the dummy gate pattern 200 may be removed to form an opening 500 in the interlayered insulating layer 400. The formation of the opening 500 may include performing a first etching process and performing a second etching process.

Referring to FIGS. 1 and 2G, the first etching process may include removing the second dummy gate pattern 220 to expose the first dummy gate pattern 210. In an embodiment, the first etching process may include etching the second dummy gate pattern 220 using an etch recipe, which is selected to have an etch selectivity with respect to the first dummy gate pattern 210. As an example, the first etching process may include a wet etching process, in which a first etching solution is used. The first etching solution may include aqueous ammonia. In certain embodiments, the first etching process may be a dry etching process. In the case where the first etching process is the dry etching process, the second dummy gate pattern 220 may not have an etch selectivity with respect to the first dummy gate pattern 210.

Referring to FIGS. 1 and 2H, the second etching process may be performed on the first dummy gate pattern 210, which is exposed by removing the second dummy gate pattern 220. The second etching process may include removing the first dummy gate pattern 210 to expose the insulating pattern 105, the device isolation patterns 130, and the spacer pattern 250. In the case where the insulating pattern 105 is omitted, the exposing of the insulating pattern 105 may mean exposing the active patterns 110. Furthermore, in the case where the insulating pattern 105 is omitted, an etch selectivity with respect to the insulating pattern 105 may mean an etch selectivity with respect to the active patterns 110. The second etching process may include etching the first dummy gate pattern 210 using an etch recipe, which is selected to have an etch selectivity with respect to the insulating pattern 105, the device isolation patterns 130, and the spacer pattern 250. The second etching process may be a process, which is distinct from the first etching process, and a condition for the second etching process may differ from a condition for the first etching process. For example, the second etching process may be performed by a wet etching process using a second etching solution, and in this case, the second etching solution may be different from the first etching solution. As an example, a solution, in which hydrogen peroxide, distilled water, and aqueous ammonia are mixed, may be used as the second etching solution. In this case, a concentration of the aqueous ammonia in the second etching solution may be lower than a concentration of the aqueous ammonia in the first etching solution.

The opening 500 may be formed by the second etching process, and the opening 500 may expose an inner side surface 250c of the spacer pattern 250, the device isolation patterns 130, and the insulating pattern 105. When viewed in a plan view, the opening 500 may be a line-shaped structure extending in the second direction D2. During the second etching process, the source/drain patterns 300 may be protected by the interlayered insulating layer 400 and the spacer pattern 250.

If the thickness A2 of the first dummy gate pattern 210 on the top surfaces 110a of the active patterns 110 is larger than 60% of the first distance A1 between the active patterns 110, it may take a long time to etch the first dummy gate pattern 210. According to an embodiment of inventive concepts, since the second dummy gate pattern 220 is provided, the thickness A2 of the first dummy gate pattern 210 on the top surfaces 110a of the active patterns 110 may be less than or equal to 60% of the first distance A1. Accordingly, it may be possible to reduce a process time for fabrication of a semiconductor device.

Hereinafter, the first dummy gate pattern 210, the second dummy gate pattern 220, the first etching process, and the second etching process will be described in more detail with reference to FIGS. 2E, 2G, and 2H.

In an embodiment, unlike that shown in FIG. 2E, the dummy gate pattern 200 may not include the first dummy gate pattern 210, and the second dummy gate pattern 220 may cover the insulating pattern 105 and the device isolation patterns 130. The second dummy gate pattern 220 may have an etch rate varying depending on its crystallographic plane. For example, in the second dummy gate pattern 220, a {111} crystallographic plane may be hardly etched, compared with {100} and {110} crystallographic planes. In the etching process to form the opening 500, it may be difficult that the second dummy gate pattern 220 has a sufficiently high etch selectivity with respect to the insulating pattern 105 or the spacer pattern 250. In this case, even when the etching process is finished, the second dummy gate pattern 220 may be left in an end region (e.g., 590 of FIG. 2H) of the opening 500. The end region 590 of the opening 500 may correspond to a region between the inner side surface 250c of the spacer pattern 250 and one of the active patterns 110 adjacent to the inner side surface 250c. The inner side surface 250c of the spacer pattern 250 may be spaced apart from the side surface 110c of the adjacent one of the active pattern 110 by a second distance A3. The second distance A3 may be smaller than the first distance A1 between the active patterns 110. For example, the first distance A1 may be 1.5 to 2.5 times the second distance A3.

In an embodiment, the dummy gate pattern 200 may include the first dummy gate pattern 210 and the second dummy gate pattern 220. A content ratio of the second semiconductor material may affect etch rates of the first dummy gate pattern 210 and the second dummy gate pattern 220. Thus, the etch rate of the first dummy gate pattern 210 by the second etching solution may be higher than the etch rate of the second dummy gate pattern 220 by the second etching solution. For example, the etch rate of the first dummy gate pattern 210 may be 10 to 100 times the etch rate of the second dummy gate pattern 220. In addition, the first dummy gate pattern 210 may further include the second semiconductor material and may have a negligible or small difference in etch rate between crystallographic planes. Thus, when a process for forming the opening 500 is finished, the first dummy gate pattern 210 may not be left in the opening 500.

Referring to FIGS. 1 and 2I, a gate insulating pattern 610 and a gate pattern 600 may be formed in the opening 500. The formation of the gate insulating pattern 610 and the gate pattern 600 may include forming a gate insulating layer to conformally cover an inner surface of the opening 500, forming a gate conductive layer to fill a remaining region of the opening 500, and performing a planarization process on the gate insulating layer and the gate conductive layer to expose the interlayered insulating layer 400 and locally form the gate insulating pattern 610 and the gate pattern 600 in the opening 500.

In an embodiment, the gate insulating pattern 610 may be formed of or include at least one of, for example, silicon oxide, silicon nitride, silicon oxynitride, or high-k dielectric materials. The high-k dielectric materials may include materials, whose dielectric constants are higher than that of silicon oxide. For example, the high-k dielectric materials may include hafnium oxide (HfO), aluminum oxide (AlO), and/or tantalum oxide (TaO). The gate pattern 600 may be formed of or include at least one of, for example, doped semiconductor materials, conductive metal nitrides, or metallic materials.

In an embodiment, the first dummy gate pattern 210 and/or its residue may not be left in the end region 590 of the opening 500. Thus, the first dummy gate pattern 210 may not be provided below the gate pattern 600. The gate insulating pattern 610 may be in direct and physical contact with the insulating pattern 105, the device isolation pattern 130, and the spacer pattern 250, in the end region 590 of the opening 500. The gate pattern 600 may be provided in the end region 590 of the opening 500. For example, the gate pattern 600 may be provided on the gate insulating pattern 610 and in a gap between the spacer pattern 250 and the active pattern 110 adjacent thereto.

A plurality of the gate patterns 600 may be provided, as shown in FIG. 1. A portion of the interlayered insulating layer 400 may be interposed between the gate patterns 600 to serve as an element separating the gate patterns 600 from each other.

Although not shown, an upper insulating layer (not shown) may be further formed on the interlayered insulating layer 400. First contact plugs (not shown) may be formed to penetrate the upper insulating layer and the interlayered insulating layer 400 and to be electrically connected to the source/drain patterns 300, and a second contact plug (not shown) may be further formed to penetrate the upper insulating layer and to be electrically connected to the gate pattern 600. Interconnection lines (not shown), which are coupled to the first and second contact plugs, may be formed on the upper insulating layer. Each of the first and second contact plugs and the interconnection lines may be formed of or include a conductive material. The semiconductor device 1 may be fabricated by the method described above. In an embodiment, the semiconductor device 1 may be a transistor.

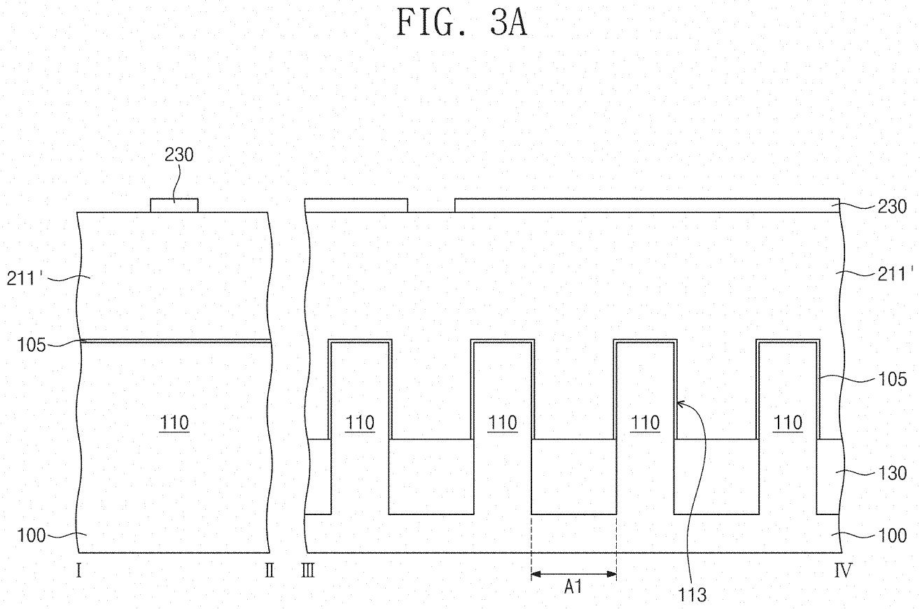

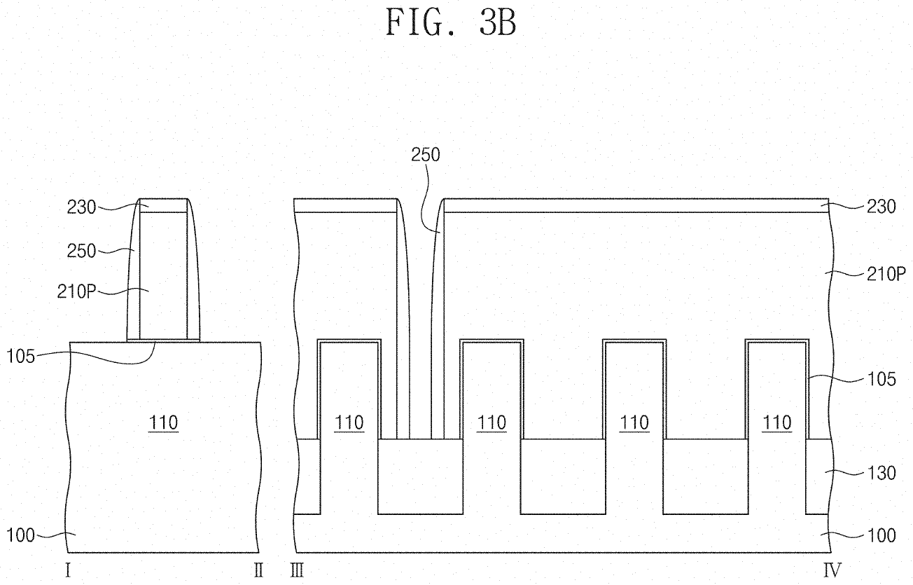

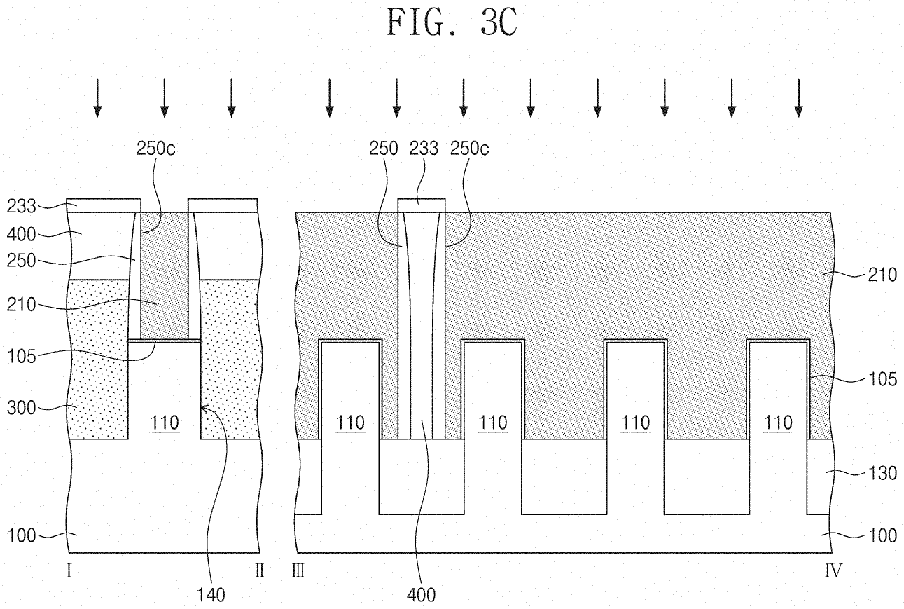

FIGS. 3A to 3C are sectional views illustrating a method of fabricating a semiconductor device according to an embodiment of inventive concepts, taken along lines I-II and III-IV of FIG. 1. For concise description, a previously described element may be identified by the same reference number without repeating an overlapping description thereof.

Referring to FIGS. 1 and 3A, the active patterns 110, the device isolation patterns 130, the insulating pattern 105, a first dummy gate layer 211′, and the mask pattern 230 may be formed on the substrate 100 by substantially the same method as that described with reference to FIGS. 2A to 2B. For example, the first dummy gate layer 211′ may be formed by the same method as that for the first dummy gate layer 211 of FIG. 2B. However, the second dummy gate layer 221 may not be formed, and the first dummy gate layer 211′ may include the first semiconductor material but may not include the second semiconductor material. The first dummy gate layer 211′ may have a crystalline structure. The first dummy gate layer 211′ may be formed of or include poly silicon.

Referring to FIGS. 1 and 3B, a preliminary dummy gate pattern 210P may be formed by patterning the first dummy gate layer 211′ through an etching process using the mask pattern 230. The preliminary dummy gate pattern 210P may be formed to cross the device isolation patterns 130 and the active patterns 110. A planar shape of the preliminary dummy gate pattern 210P may be substantially the same as that of the first dummy gate pattern 210 described with reference to FIG. 2C. The spacer patterns 250 may be formed on side surfaces of the preliminary dummy gate pattern 210P.

Referring to FIGS. 1 and 3C, the recess portions 140, the source/drain patterns 300, and the interlayered insulating layer 400 may be formed by the method described with reference to FIGS. 2D and 2E. The mask pattern 230 may be removed during the process of forming the interlayered insulating layer 400. Thereafter, a mask layer 233 may be formed on the interlayered insulating layer 400 to cover the top surface of the interlayered insulating layer 400 and the top surface of the spacer pattern 250.

An ion implantation process may be performed on the preliminary dummy gate pattern 210P exposed through the mask layer 233. The ion implantation process may be performed to inject the second semiconductor material into the preliminary dummy gate pattern 210P, and as a result, the first dummy gate pattern 210 may be formed. The first dummy gate pattern 210 may include the first semiconductor material and the second semiconductor material. A content of the second semiconductor material in the first dummy gate pattern 210 may range from 0.1 at % to 80 at %. In certain embodiments, the ion implantation process may be performed to additionally inject a first material (e.g., P, As, B, C, Ar, N, and/or F) into the preliminary dummy gate pattern 210P. In this case, a total content of the second semiconductor material and the first material in the first dummy gate pattern 210 may range from 0.1 at % to 80 at %.

The spacer pattern 250 may be interposed between the side surface of the first dummy gate pattern 210 and the side surfaces of the source/drain patterns 300. In an embodiment, during the ion implantation process, the second semiconductor material may be further injected into the inner side surface 250c of the spacer pattern 250. For example, at least a portion of the second semiconductor material may be injected in a tilted manner, and in this case, the second semiconductor material may be included in the spacer pattern 250. In the tilted manner, an injection direction of the second semiconductor material may be inclined at an angle relative to a direction that is perpendicular to the bottom surface of the substrate 100.

Referring back to FIG. 2H, a second etching process may be performed on the first dummy gate pattern 210 to form the opening 500. The process condition and the etch recipe for the second etching process may be the same as those described above. The second etching process may be performed at a temperature of about 25° C.-150° C. In the case where the total content of the second semiconductor material and the first material in the first dummy gate pattern 210 is less than 0.1 at % or greater than 80 at %, an etch selectivity of the first dummy gate pattern 210 with respect to the insulating pattern 105, the device isolation patterns 130, and the spacer pattern 250 in the second etching process may be reduced. According to an embodiment of inventive concepts, the total content of the second semiconductor material and the first material in the first dummy gate pattern 210 may range from 0.1 at % to 80 at %, and thus, an etch rate of the first dummy gate pattern 210 may be sufficiently greater than etch rates of the insulating pattern 105, the active patterns 110, the device isolation patterns 130, and the spacer pattern 250. After the second etching process, the first dummy gate pattern 210 and/or residues thereof may not be left in the opening 500. In the present specification, in the case where the first dummy gate pattern 210 does not include the first material, the total content or atomic percent of the second semiconductor material and the first material may mean that of the second semiconductor material.

Referring to FIG. 2I, the gate insulating pattern 610 and the gate pattern 600 may be formed in the opening 500. Accordingly, the fabrication of the semiconductor device 1 may be finished. However, in an embodiment, the spacer pattern 250 may further include the second semiconductor material.

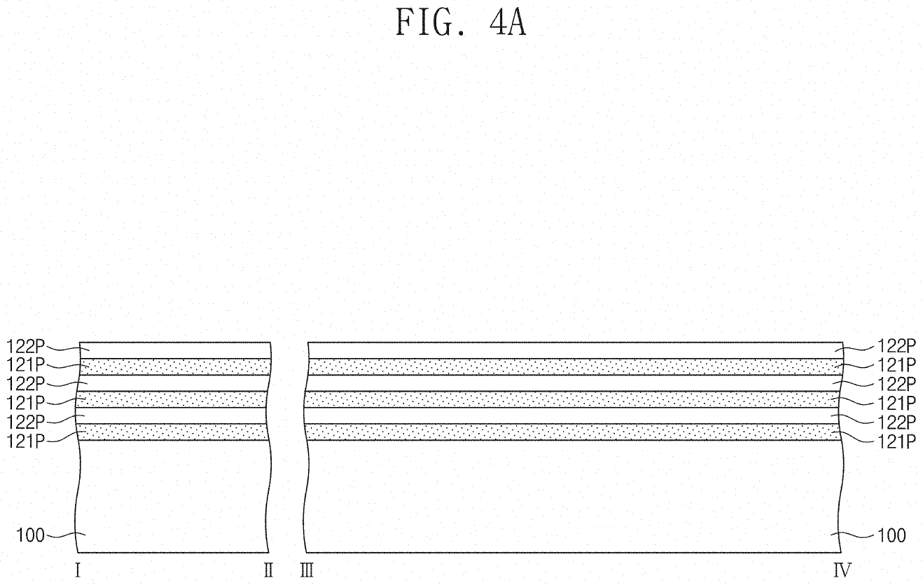

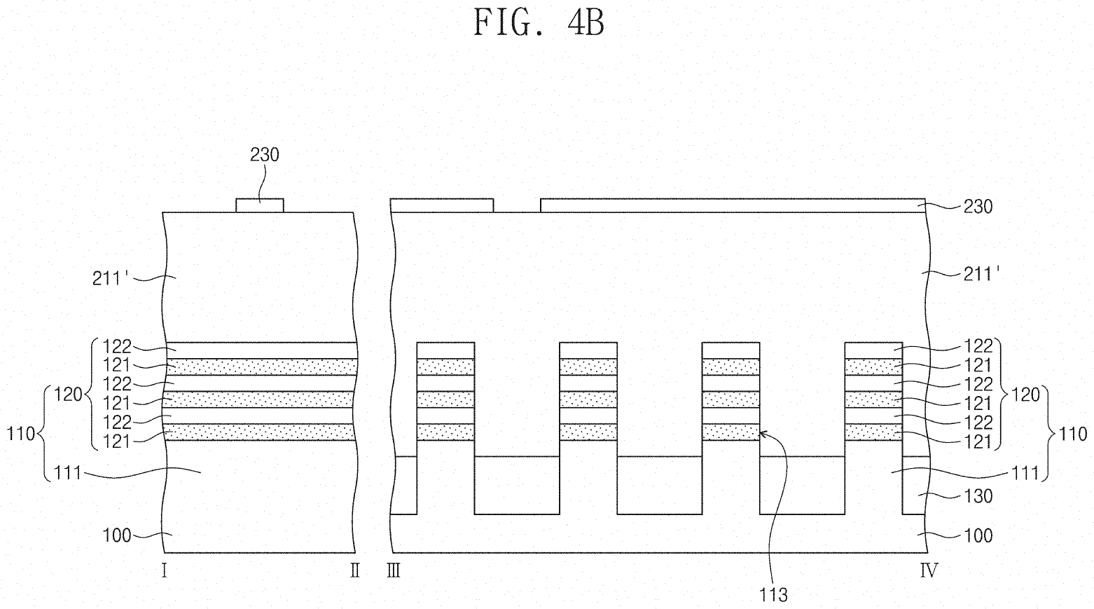

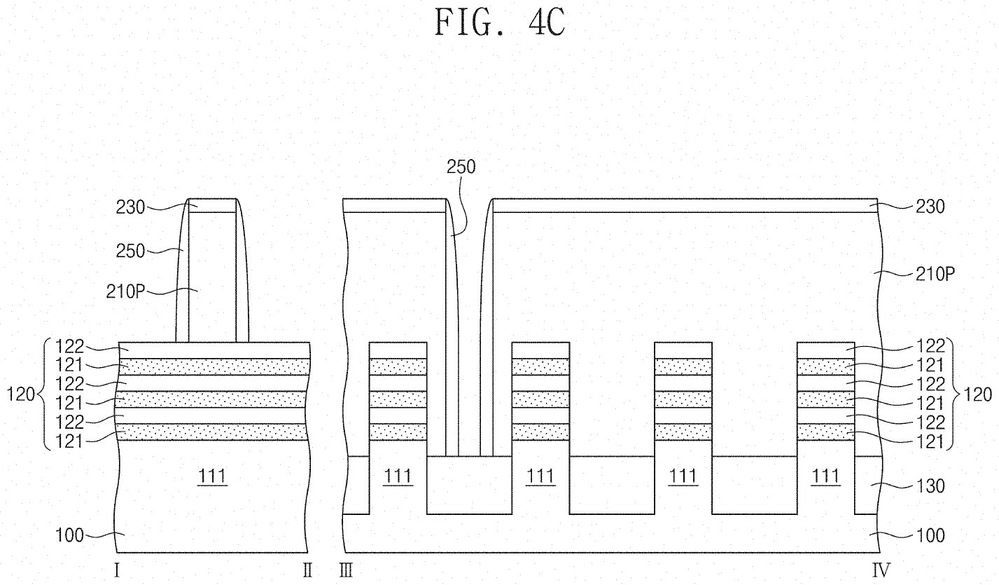

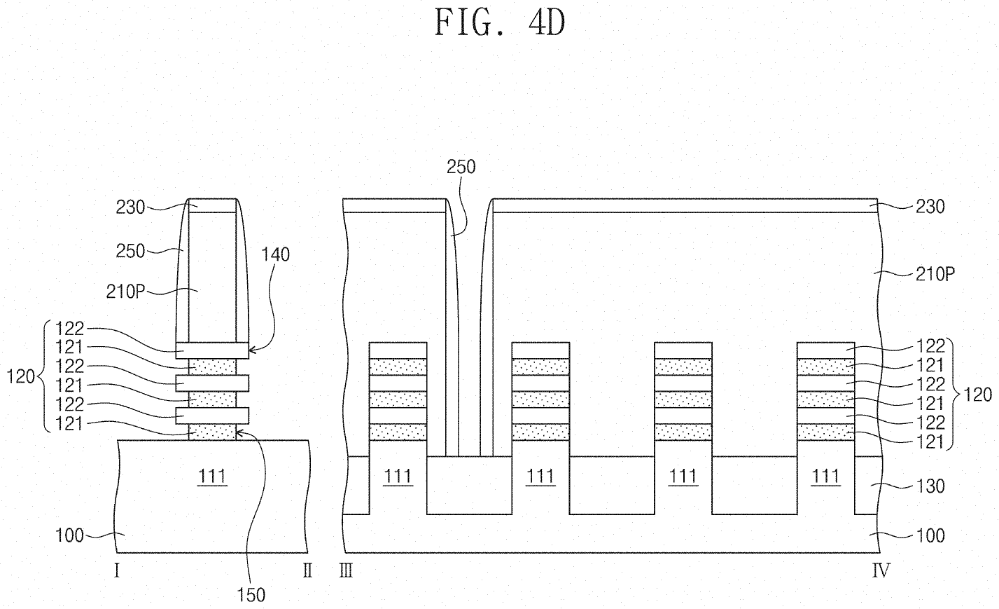

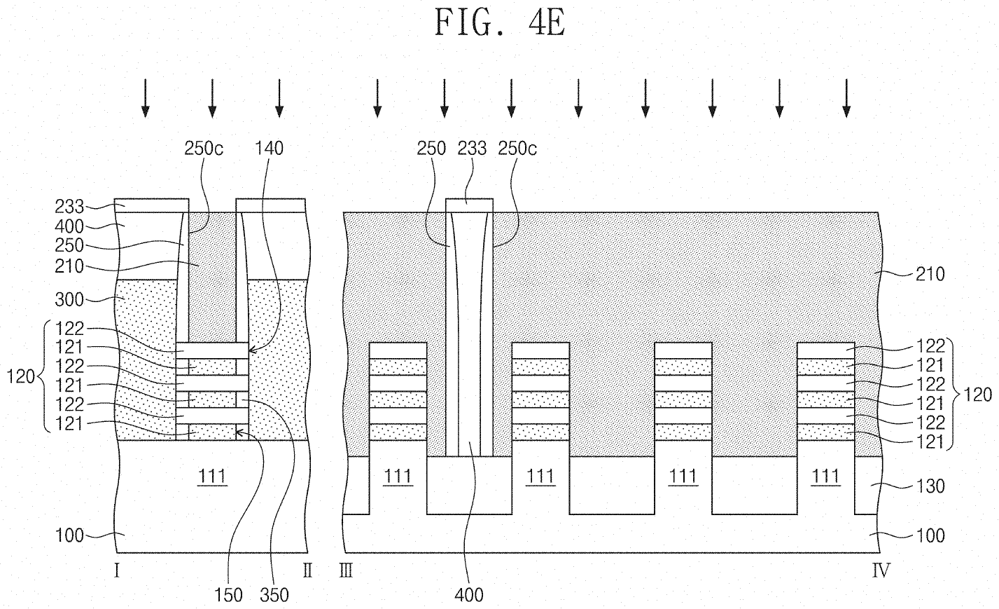

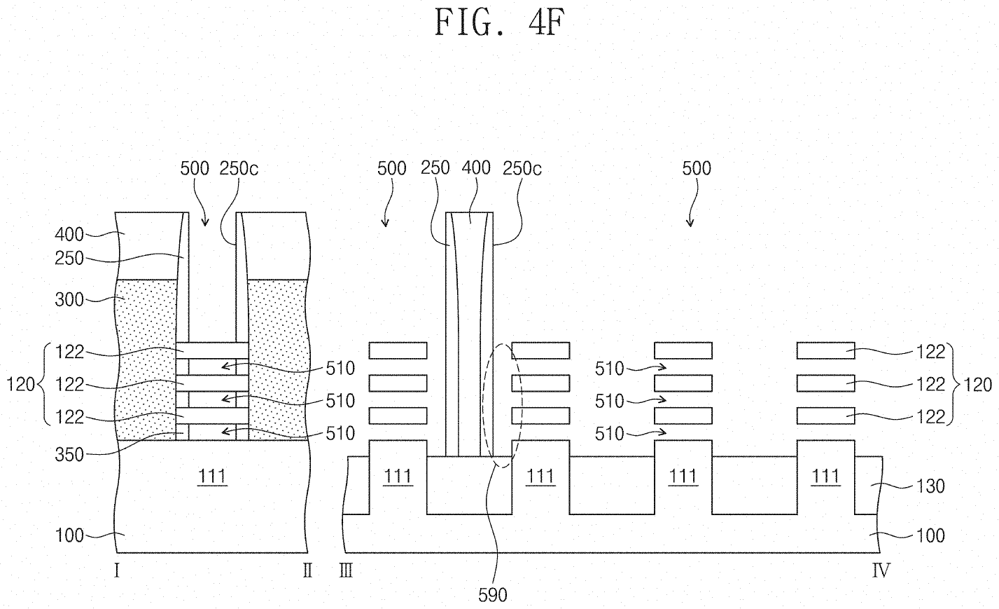

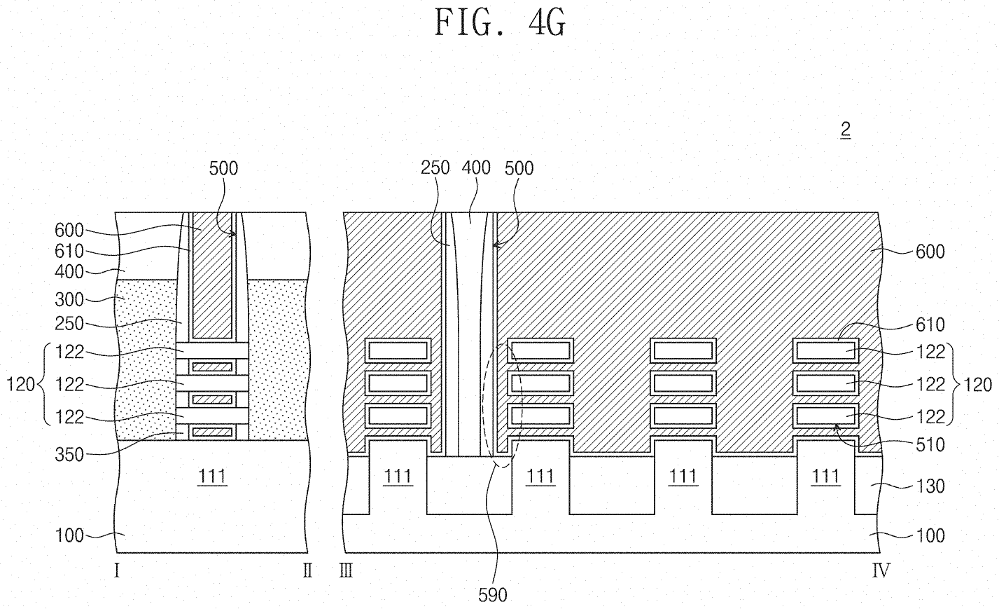

FIGS. 4A to 4G are sectional views illustrating a method of fabricating a semiconductor device according to an embodiment of inventive concepts, taken along lines I-II and III-IV of FIG. 1.

Referring to FIGS. 1 and 4A, first semiconductor layers 121P and second semiconductor layers 122P may be stacked on the substrate 100. The first semiconductor layers 121P and the second semiconductor layers 122P may be formed through an epitaxial growth process, in which the substrate 100 is used as an seed layer. The first semiconductor layers 121P and the second semiconductor layers 122P may be successively formed in the same chamber. The first semiconductor layers 121P and the second semiconductor layers 122P may be conformally grown from the entire surface of the substrate 100, not from a specific region of the substrate 100 (e.g., not by a selective epitaxial growth process). The first semiconductor layers 121P and the second semiconductor layers 122P may be alternately and repeatedly stacked on the substrate 100. The number of the first semiconductor layers 121P and the number of the second semiconductor layers 122P may be variously changed. The first semiconductor layers 121P may serve as sacrificial layers or channel regions of transistors. Each of the first semiconductor layers 121P may be a germanium-containing layer. The first semiconductor layers 121P may further include dopants, and in an embodiment, the dopants may include at least one of Al, Ga, Sb, As, In, Ge, Zr, Hf, or Ta. As an example, each of the first semiconductor layers 121P may be an aluminum-doped silicon-germanium (SiGe) layer. Each of the first semiconductor layers 121P may have a uniform composition ratio. Each of the second semiconductor layers 122P may be a silicon-containing layer (e.g., a silicon layer). For example, the second semiconductor layers 122P may be formed of or include poly silicon.

Referring to FIGS. 1 and 4B, the active patterns 110 may be formed on the substrate 100. Each of the active patterns 110 may include a base active pattern 111 and an upper active pattern 120. The formation of the base active pattern 111 and the upper active pattern 120 may include patterning the first semiconductor layers 121P, the second semiconductor layers 122P, and an upper portion of the substrate 100 to form the trenches 113. The base active pattern 111 and the upper active pattern 120 may be defined by the trenches 113. The active patterns 110 and the trenches 113 may have substantially the same planar shapes as those described with reference to FIGS. 1 and 2A.

Each of the upper active patterns 120 may include first semiconductor patterns 121 and second semiconductor patterns 122, which are stacked. The first semiconductor patterns 121 may be formed by patterning the first semiconductor layers 121P. The second semiconductor patterns 122 may be formed by pattering the second semiconductor layers 122P. Each of the upper active patterns 120 may be a line-shaped structure extending in the first direction D1. The first semiconductor patterns 121 and the second semiconductor patterns 122 may be alternately and repeatedly stacked in a direction perpendicular to the bottom surface of the substrate 100. Each of the first and second semiconductor patterns 121 and 122 may be a line-shaped pattern extending in the first direction D1. Top surfaces of the upper active patterns 120 may correspond to top surfaces of the topmost ones of the second semiconductor patterns 122. Side surfaces 200c of the upper active patterns 120 may include side surfaces of the first semiconductor patterns 121 and side surfaces of the second semiconductor patterns 122.

A plurality of base active patterns 111 may be formed by pattering an upper portion of the substrate 100. Each of the base active patterns 111 may be a line-shaped structure extending in the first direction D1, and the upper active patterns 120 may be formed on top surfaces of the base active patterns 111, respectively.

The device isolation patterns 130 may be formed on side surfaces of the base active patterns 111. Top surfaces of the device isolation patterns 130 may be located at a level lower than the top surface of the base active pattern 111. Hereinafter, one of the base active patterns 111 will be mentioned in the following description.

The first dummy gate layer 211′ may be formed on the upper active patterns 120 and the device isolation patterns 130. The first dummy gate layer 211′ may be substantially the same as that described with reference to FIG. 3A. For example, the first dummy gate layer 211′ may include the first semiconductor material but may not include the second semiconductor material. The mask pattern 230 may be formed on the first dummy gate layer 211′.

Referring to FIGS. 1 and 4C, the preliminary dummy gate pattern 210P may be formed by patterning the first dummy gate layer 211′ through an etching process using the mask pattern 230. The spacer pattern 250 may be formed on the upper active patterns 120 to cover side surfaces of the preliminary dummy gate pattern 210P.

Referring to FIGS. 1 and 4D, the recess portions 140 may be formed in the upper active patterns 120 and at both sides of the spacer pattern 250. The formation of the recess portions 140 may include etching portions of the upper active patterns 120, using the mask pattern 230 and the spacer pattern 250 as an etch mask. The side surfaces of the first and second semiconductor patterns 121 and 122 and the top surface of the base active pattern 111 may be exposed through the recess portions 140.

Portions of the first semiconductor patterns 121 may be further removed in a horizontal direction to form recess regions 150. The recess regions 150 may be formed between the lowermost one of the second semiconductor patterns 122 and the base active pattern 111 and between the second semiconductor patterns 122. The formation of the recess regions 150 may include performing an etching process, in which an etching source having an etch selectivity with respect to the first semiconductor patterns 121 is used, on side surfaces of the first semiconductor patterns 121.

Referring to FIGS. 1 and 4E, insulating spacers 350 may be formed in the recess regions 150, respectively. The insulating spacers 350 may cover the recessed side surfaces of the first semiconductor patterns 121. The formation of the insulating spacers 350 may include forming a barrier insulating layer (not shown) on the side surfaces of the first and second semiconductor patterns 121 and 122 to conformally cover the recess regions 150, and performing an anisotropic etching process on the barrier insulating layer. The insulating spacers 350 may be formed of or include at least one of, for example, silicon nitride and/or silicon carbo oxynitride. The recess regions 150 and the insulating spacers 350 may not be formed, unlike that illustrated in the drawings.

The source/drain patterns 300 may be formed on the base active patterns 111 and at both sides of the dummy gate pattern 200. The source/drain patterns 300 may be formed by a selective epitaxial growth process, in which the second semiconductor patterns 122 and the base active pattern 111 are used as a seed layer. Each of the source/drain patterns 300 may be in physical contact with the top surface of the base active pattern 111, the exposed side surfaces of the second semiconductor patterns 122, the insulating spacers 350, and the spacer pattern 250. The spacer pattern 250 may be interposed between the side surface of the first dummy gate pattern 210 and the side surfaces of the source/drain patterns 300. In other words, the source/drain patterns 300 may be horizontally spaced apart from the first dummy gate pattern 210, with the spacer pattern 250 interposed therebetween. The insulating spacers 350 may be respectively interposed between the source/drain patterns 300 and the first semiconductor patterns 121.

The interlayered insulating layer 400 may be formed on the source/drain patterns 300. The mask pattern 230 may be removed during the process of forming the interlayered insulating layer 400. Thereafter, the mask layer 233 may be formed on the interlayered insulating layer 400 and the spacer pattern 250.

An ion implantation process, in which the mask layer 233 is used as an ion mask, may be performed on the preliminary dummy gate pattern 210P. The second semiconductor material may be injected into the preliminary dummy gate pattern 210P, and as a result, the first dummy gate pattern 210 may be formed. A content of the second semiconductor material in the first dummy gate pattern 210 may range from 0.1 at % to 80 at %. In certain embodiments, the ion implantation process may be performed to additionally inject a first material (e.g., P, As, B, C, Ar, N, and/or F) into the preliminary dummy gate pattern 210P. In this case, the total content of the second semiconductor material and the first material in the first dummy gate pattern 210 may range from 0.1 at % to 80 at %. The ion implantation process may be performed by substantially the same method as that described with reference to FIG. 3C. As a result of the ion implantation process, the second semiconductor material may be further injected into the inner side surface 250c of the spacer pattern 250.

Referring to FIGS. 1 and 4F, the second etching process may be performed on the first dummy gate pattern 210 to form the opening 500. The process condition and the etch recipe for the second etching process may be the same as those described above. The opening 500 may be formed to expose the first and second semiconductor patterns 121 and 122 and the inner side surface 250c of the spacer pattern 250. The first semiconductor patterns 121 exposed by the opening 500 may be removed by the second etching process, and thus, gate openings 510 may be formed. The gate openings 510 may be empty regions. The gate openings 510 may be formed between the second semiconductor patterns 122 and between the lowermost one of the second semiconductor patterns 122 and the base active pattern 111. The gate openings 510 may be connected to the opening 500. In certain embodiments, the formation of the gate openings 510 may be performed through an additional etching process, which is distinct from the second etching process. As a result of the formation of the gate openings 510, the upper active patterns 120 may include the second semiconductor patterns 122, which are spaced apart from each other. The second semiconductor patterns 122 may be spaced apart from each other in a direction perpendicular to the bottom surface of the substrate 100.

According to an embodiment of inventive concepts, the total content of the second semiconductor material and the first material in the first dummy gate pattern 210 may range from 0.1 at % to 80 at %, and thus, an etch rate of the first dummy gate pattern 210 may be sufficiently greater than etch rates of the active patterns 110, the device isolation patterns 130, and the spacer pattern 250. After the second etching process, the first dummy gate pattern 210 and/or residues thereof may not be left in the opening 500 (e.g., in the end region 590 of the opening 500).

Referring to FIGS. 1 and 4G, the gate insulating pattern 610 and the gate pattern 600 may be formed in the opening 500 and the gate openings 510. The formation of the gate insulating pattern 610 and the gate pattern 600 may include forming a gate insulating layer to conformally cover inner surfaces of the opening 500 and the gate openings 510, forming a gate conductive layer to fill remaining regions of the opening 500 and the gate openings 510, and performing a planarization process on the gate insulating layer and the gate conductive layer to expose the interlayered insulating layer 400 and to locally form the gate insulating pattern 610 and the gate pattern 600 in the opening 500 and the gate openings 510.

The gate insulating pattern 610 may cover the base active pattern 111, the device isolation patterns 130, the second semiconductor patterns 122, and the spacer pattern 250. The gate pattern 600 may fill the opening 500 and the gate openings 510. The gate pattern 600 may cover the gate insulating pattern 610 and may be spaced apart from the second semiconductor patterns 122 and the base active pattern 111. The gate pattern 600 may be spaced apart from the source/drain patterns 300, with the insulating spacers 350 and the spacer pattern 250 interposed therebetween.

Each of the second semiconductor patterns 122 may serve as a channel of a transistor. The second semiconductor patterns 122 may serve as a bridge channel or a nano wire channel connecting the source/drain patterns 300. Each of the source/drain patterns 300 may be in physical contact with the second semiconductor patterns 122. The source/drain patterns 300 may be spaced apart from each other with the second semiconductor patterns 122 interposed therebetween. The second semiconductor patterns 122 and the source/drain patterns 300 may constitute an active structure provided on the base active pattern 111. The active structure and the gate pattern 600 may constitute a gate-all-around type field effect transistor. The semiconductor device 2 may be fabricated by the method described above.

According to an embodiment of inventive concepts, a first dummy gate pattern may include a first semiconductor material and a second semiconductor material. The first dummy gate pattern may have a negligible or small difference in etch rate between crystallographic planes. An opening may be formed by etching the first dummy gate pattern. After the etching of the first dummy gate pattern, the first dummy gate pattern and/or residues thereof may not be left in the opening. Accordingly, the first dummy gate pattern may not be provided below a gate pattern. It may be possible to improve reliability of a semiconductor device.

While example embodiments of inventive concepts have been particularly shown and described, it will be understood by one of ordinary skill in the art that variations in form and detail may be made therein without departing from the spirit and scope of the attached claims.

What is claimed is:

1. A method of fabricating a semiconductor device, comprising:
forming an active pattern on a substrate;
forming a first dummy gate pattern, which is extended to cross the active pattern, on the active pattern, the first dummy gate pattern including a first semiconductor material and a second semiconductor material different from the first semiconductor material;
forming a spacer pattern to cover a side surface of the first dummy gate pattern; and
forming a source/drain pattern at a side of the first dummy gate pattern,
the spacer pattern being between the side surface of the first dummy gate pattern and a side surface of the source/drain pattern.

2. The method of claim 1, further comprising:
forming a second dummy gate pattern on the first dummy gate pattern.

3. The method of claim 2, wherein the second dummy gate pattern includes the first semiconductor material but does not include the second semiconductor material.

4. The method of claim 2, further comprising:
performing a first etching process to remove the second dummy gate pattern and to expose the first dummy gate pattern; and
performing a second etching process to remove the first dummy gate pattern,
wherein a process condition for the second etching process is different from a process condition for the first etching process.

5. The method of claim 4, wherein
the first etching process includes a wet etching process using a first etching solution or a dry etching process,
the second etching process includes a wet etching process using a second etching solution, and
the second etching solution includes a material different from the first etching solution.

6. The method of claim 5, wherein
the first etching solution comprises aqueous ammonia, and
the second etching solution includes hydrogen peroxide, distilled water, and aqueous ammonia.

7. The method of claim 6, wherein a concentration of the aqueous ammonia in the second etching solution is lower than a concentration of the aqueous ammonia in the first etching solution.

8. The method of claim 1, further comprising:
forming an interlayered insulating layer to cover the source/drain pattern and the spacer pattern; and
forming a mask layer to cover the interlayered insulating layer and the spacer pattern,
wherein
the forming the first dummy gate pattern includes forming a preliminary dummy gate pattern on the active pattern and forming the spacer pattern to cover a side surface of the preliminary dummy gate pattern before the forming the interlayer insulating layer, and
the forming the mask layer, and the forming the first dummy gate pattern further includes injecting the second semiconductor material into the preliminary dummy gate pattern using the mask layer after the forming the mask layer.

9. The method of claim 1, wherein a content of the second semiconductor material in the first dummy gate pattern ranges from 0.1 at % to 80 at %.

10. The method of claim 1, wherein the active pattern includes first semiconductor patterns and second semiconductor patterns, which are stacked on each other.

11. The method of claim 1, further comprising:
etching the first dummy gate pattern to form an opening exposing an inner side surface of the spacer pattern; and
forming a gate pattern in the opening, wherein
the first dummy gate pattern is not left in the opening after the etching of the first dummy gate pattern.

12. The method of claim 1, further comprising:
forming a device isolation pattern to cover a lower side surface of the active pattern,
wherein a top surface of the first dummy gate pattern on the device isolation pattern is provided at a level that is equal to or higher than a top surface of the active pattern.

13. The method of claim 1, wherein the forming the active pattern forms the active pattern to protrude above the substrate.

14. A method of fabricating a semiconductor device, comprising:
forming a trench on a substrate, the trench defining an active pattern in the substrate;
forming a device isolation pattern to cover a lower portion of the trench;
forming a first dummy gate pattern on the active pattern and the device isolation pattern, the first dummy gate pattern crossing over the active pattern and the device isolation pattern, a top surface of the first dummy gate pattern on the device isolation pattern being at a level that is equal to or higher than a top surface of the active pattern; and
forming a second dummy gate pattern on the first dummy gate pattern.

15. The method of claim 14, wherein
the forming the trench defines a plurality of active patterns in the substrate,
the plurality of active patterns include the active pattern, and
a thickness of the first dummy gate pattern on top surfaces of the plurality of active patterns is 40% to 60% of a distance between adjacent active patterns among the plurality of active patterns.

16. A method of fabricating a semiconductor device, comprising:
forming an active pattern, which has an upward protruding shape, on a substrate; and
forming a dummy gate pattern on the active pattern, the dummy gate pattern crossing the active pattern and extending in a direction,
the forming the dummy gate pattern including forming a first dummy gate pattern to cover a side surface of the active pattern and forming a second dummy gate pattern on the first dummy gate pattern,
the first dummy gate pattern including a first semiconductor material and a second semiconductor material that is different from the first semiconductor material.

17. The method of claim 16, further comprising,
forming a spacer pattern on a side surface of the dummy gate pattern; and
forming a source/drain pattern in the active pattern and at a side of the dummy gate pattern,
wherein the spacer pattern is between a side surface of the first dummy gate pattern and a side surface of the source/drain pattern.

18. The method of claim 16, further comprising:
performing a first etching process on the second dummy gate pattern to expose the first dummy gate pattern, and
performing a second etching process on the first dummy gate pattern to remove the first dummy gate pattern.

19. The method of claim 18, wherein
the first etching process is performed using a first etching solution including aqueous ammonia,
the second etching process is performed using a second etching solution that includes a mixture of hydrogen peroxide, distilled water, and aqueous ammonia.

20. The method of claim 19, wherein a concentration of the aqueous ammonia in the second etching solution is lower than a concentration of the aqueous ammonia in the first etching solution.
